(19) United States
(12) Patent Application Publication
(10) Pub. No.: US 2017/0032850 A1
(43) Pub. Date: Feb. 2, 2017

(54) SEMICONDUCTOR MEMORY APPARATUS AND TEST METHOD THEREOF

(71) Applicant: SK hynix Inc., Icheon-si Gyeonggi-do (KR)

(72) Inventors: Seung Kyun LIM, Icheon-si Gyeonggi-do (KR); Ho Seok EM, Icheon-si Gyeonggi-do (KR)

(21) Appl. No.: 15/049,900

(22) Filed: Feb. 22, 2016

(30) Foreign Application Priority Data
Jul. 31, 2015 (KR) 10-2015-0109026

(51) Int. Cl. G11C 29/38; G11C 29/44; G11C 13/00

(52) U.S. Cl. CPC G11C 29/38; G11C 13/0097; G11C 13/0069; G11C 29/44

(57) ABSTRACT

A semiconductor memory apparatus includes a normal write pulse generator configured to generate a normal write pulse in a normal operation, a test write pulse generator configured to repeatedly generate a test write pulse a preset number of times in a test operation, and a selector configured to provide the normal write pulse to a memory cell in the normal operation and provide the test write pulse to the memory cell in the test operation.

### CROSS-REFERENCES TO RELATED APPLICATION

This application claims priority under 35 U.S.C. 119(a) to Korean application No. 10-2015-0109026 filed on Jul. 31, 2015, in the Korean intellectual property Office, which is incorporated herein by reference in its entirety.

### BACKGROUND

1. Technical Field

Various embodiments of the present invention generally relates to a semiconductor integrated circuit, and more particularly to a semiconductor memory apparatus and a test method thereof.

2. Related Art

Semiconductor memories are electronic components that stores data and output the stored data. The semiconductor memories have a large number of memory cells.

The memory cells constituting the semiconductor memory may wear out after performing reading and writing operations thereon a large number of times.

For that reason, a test may be performed on the semiconductor memories to check how many times the reading and writing operations can be performed without errors. With their growing density and capacity, the test time increases. Test time reduction, therefore, is a key issue in testing the semiconductor memories.

### SUMMARY

According to an embodiment, there is provided a semiconductor memory apparatus. The semiconductor memory apparatus may include a normal write pulse generator configured to generate a normal write pulse in a normal operation; a test write pulse generator configured to repeatedly generate a test write pulse a preset number of times in a test; and a selector configured to provide the normal write pulse to a memory cell in the normal operation and provide the test write pulse to the memory cell in the test.

According to an embodiment, there is provided a semiconductor memory apparatus. The semiconductor memory apparatus may include a normal write pulse generator configured to generate a normal write pulse; a test write pulse generator configured to generate a test write pulse and a test activation signal in response to a test signal; a selector configured to provide one of the normal write pulse and the test write pulse to a memory cell as a selection pulse in response to the test signal; a sense amplifier controller configured to generate a sense amplifier activation signal in response to a sense amplifier enable signal and the test activation signal; and a sense amplifier configured to sense and amplify cell information provided from the memory cell and output the sense-amplified cell information as data in response to the sense amplifier activation signal.

According to an embodiment, there is provided a test method. The test method may include enabling a test signal; repeatedly generating a test write pulse when the test signal is enabled; determining whether or not the test write pulse is generated a preset number of times; continuously performing generation of the test write pulse or stopping the generation of the test write pulse according to a result of the determining whether or not the test write pulse is generated the preset number of times; and testing endurance of a memory cell when the generation of the test write pulse is stopped.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a configuration diagram illustrating a semiconductor memory apparatus according to an embodiment of the inventive concept;

FIG. 2 is a configuration diagram illustrating a test write pulse generator of FIG. 1;

FIG. 3 is a configuration diagram illustrating a sense amplifier controller of FIG. 1; and

FIG. 4 is a flowchart illustrating a test method of a semiconductor memory apparatus according to an embodiment of the inventive concept.

### DETAILED DESCRIPTION

Hereinafter, exemplary embodiments will be described in greater detail with reference to the accompanying drawings. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

The inventive concept is described herein with reference to cross-section and/or plan illustrations that are schematic illustrations of idealized embodiments of the inventive concept. However, embodiments of the inventive concept should not be limited construed as limited to the inventive concept. Although a few embodiments of the inventive concept will be shown and described, it will be appreciated by those of ordinary skill in the art that changes may be made in these exemplary embodiments without departing from the principles and spirit of the inventive concept.

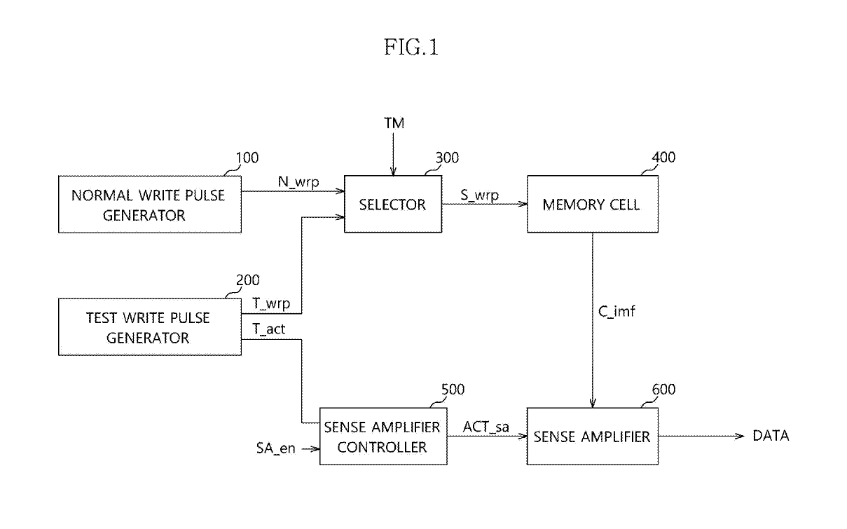

As illustrated in FIG. 1, a semiconductor memory apparatus according to an embodiment may include a normal write pulse generator 100, a test write pulse generator 200, a selector 300, a memory cell 400, a sense amplifier controller 500, and a sense amplifier 600.

The normal write pulse generator 100 may generate a normal write pulse N_wrp in a non-test operation, which is a normal operation such as reading and writing operations. For example, in the normal operation, the normal write pulse generator 100 may generate the normal write pulse N_wrp in response to a write command.

The test write pulse generator 200 may generate a test write pulse T_wrp and a test activation signal T_act in a test operation. For example, the test write pulse generator 200 may enable the test activation signal T_act when a test signal TM is enabled, and generate the test write pulse T_wrp a preset number of times. After the test write pulses T_wrp have been generated the preset number of times, the test write pulse generator 200 may disable the test activation signal T_act.

The selector 300 may output the normal write pulse N_wrp as a selection pulse S_wrp in the normal operation, and output the test write pulse T_wrp as the selection pulse S_wrp in the test operation. For example, the selector 300 may output one of the normal write pulse N_wrp and the test write pulse T_wrp as the selection pulse S_wrp in response to the test signal TM. More specifically, the selector 300 may output the normal write pulse N_wrp as the selection pulse S_wrp when the test signal TM is disabled, and output the test write pulse T_wrp as the selection pulse S_wrp when the test signal TM is enabled. The selector 300 may include a multiplexer, a switch, or the like.

The memory cell 400 may store data in response to the selection pulse S_wrp. For example, the memory cell 400 may store a voltage of a data signal, or the memory cell 400 may store data corresponding to a pulse width of the selection pulse S_wrp. In an embodiment, the memory cell 400 may include a capacitor. In another embodiment, the memory cell 400 may include a resistive memory device. In another embodiment, the memory cell may include a transistor having a floating gate.

The sense amplifier controller 500 may generate a sense amplifier activation signal ACT_sa in response to the test activation signal T_act and a sense amplifier enable signal SA_en. For example, the sense amplifier controller 500 may disable the sense amplifier activation signal ACT_sa regardless of the sense amplifier enable signal SA_en when the test activation signal T_act is enabled. The sense amplifier controller 500 may enable the sense amplifier activation signal ACT_sa in response to the sense amplifier enable signal SA_en when the test activation signal T_act is disabled. More specifically, the sense amplifier controller 500 may enable the sense amplifier activation signal ACT_sa when the test activation signal T_act is disabled and the sense amplifier enable signal SA_en is enabled. The sense amplifier controller 500 may disable the sense amplifier activation signal ACT_sa when the test activation signal T_act is disabled and the sense amplifier enabled signal SA_en is disabled.

When the sense amplifier activation signal ACT_sa is enabled, the sense amplifier 600 may sense and amplify cell information C_imf provided from the memory cell 400 and output the amplified cell information C_imf as data DATA. When the sense amplifier activation signal ACT_sa is disabled, the sense amplifier 600 may not perform a sense-amplifying operation on the cell information C_imf.

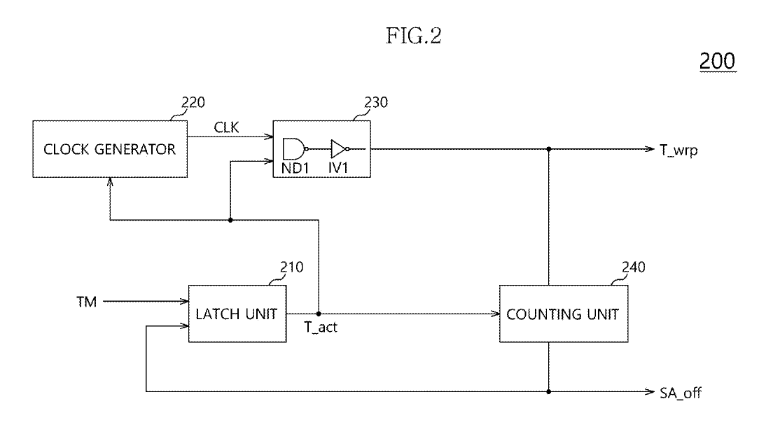

As illustrated in FIG. 2, the test write pulse generator 200 may include a latch unit 210, a clock generator 220, an output controller 230, and a counting unit 240.

The latch unit 210 may generate the test activation signal T_act in response to the test signal TM and a reset signal RST. For example, when the test signal TM is enabled, the latch unit 210 may enable the test activation signal T_act until the reset signal RST becomes enabled. More specifically, the latch unit 210 may enable the test activation signal T_act when the test signal TM is enabled, and disable the test activation signal T_act when the reset signal RST is enabled. The latch unit 210 may include one or more of a D-flip flop circuit, a SR latch, and the like.

The clock generator 220 may generate a clock CLK in response to the test activation signal T_act. For example, the clock generator 220 may generate the clock CLK in a period when the test activation signal T_act is enabled. Here, the clock CLK may be a signal that periodically transitions between preset voltage levels. When the test activation signal T_act is disabled, the clock generator 220 may not generate the clock CLK, and may maintain the level of the clock CLK at a certain voltage.

The output controller 230 may output the clock CLK as the test write pulse T_wrp in response to the test activation signal T-act. For example, the output controller 230 may output the clock CLK as the test write pulse T_wrp by driving the clock CLK in the period when the test activation signal T_act is enabled.

The output controller 230 may include a first NAND gate ND1 and a first inverter IV1. The first NAND gate ND1 may receive the clock CLK and the test activation signal T_act. The first inverter IV1 may receive an output signal of the NAND gate ND1 and output the test write pulse T_wrp.

The output controller 230 in accordance with an embodiment may output the clock CLK as the test write pulse T_wrp in the period when the test activation signal T_act is enabled (e.g., when the test activation signal T_act is pulled up to a logic high level).

The counting unit 240 may generate the reset signal RST in response to the test activation signal T_act and the test write pulse T_wrp. For example, when the test activation signal T_act is enabled, the counting unit 240 may disable the reset signal RST and count the number of pulses in the test write pulse T_wrp. The counting unit 240 may count the number of pulses in the test write pulse T_wrp in the period when the test activation signal T_act is enabled, and enable the reset signal RST when the counting value of the test write pulse T_wrp reaches a preset value.

When the test signal TM is enabled, the test write pulse generator 200 in accordance with an embodiment may enable the test activation signal T_act, and repeatedly generate the test write pulse T_wrp. The test write pulse generator 200 may stop generating the test write pulse T_wrp and disable the test activation signal T_act after the test write pulses T_wrp have been generated the preset number of times.

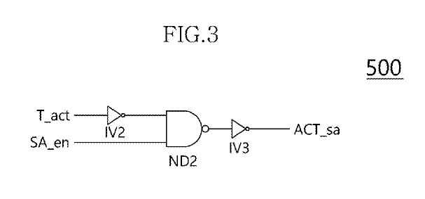

As illustrated in FIG. 3, the sense amplifier controller 500 may include a second NAND gate ND2 and second and third inverters IV2 and IV3. The second inverter IV2 may receive the test activation signal T_act. The NAND gate ND2 may receive an output signal of the second inverter IV2 and the sense amplifier enable signal SA_en. The third inverter IV3 may receive an output signal of the second NAND gate ND2 and output the sense amplifier activation signal ACT_sa.

The sense amplifier controller 500 in accordance with an embodiment may disable the sense amplifier activation signal ACT_sa to a logic low level regardless of the sense amplifier enable signal SA_en in the period when the test activation signal T_act is enabled (e.g., when the test activation signal T_act is pulled up to the logic high level). The sense amplifier controller 500 may generate the sense amplifier activation signal ACT_sa in response to the sense amplifier enable signal SA_en in a period that the test activation signal T_act is disabled to the logic low level. More specifically, the sense amplifier controller 500 may enable the sense amplifier activation signal ACT_sa to the high level when the test activation signal T_act is disabled and the sense amplifier enable signal SA_en is enabled (e.g., when the test activation signal T_act is pulled down to the logic low level and the sense amplifier enable signal SA_en is pulled up to the logic high level). The sense amplifier controller 500 may disable the sense amplifier activation signal ACT_sa when the test activation signal T_act is disabled and the sense amplifier enable signal SA_en is disabled (e.g., when both the test activation signal T_act and the sense amplifier enable signal SA_en are pulled down to the logic low level).

An operation of the semiconductor memory apparatus in accordance with an embodiment will be described below.

In the normal operation, the normal write pulse generator 100 may be activated, and the test write pulse generator 200 may be inactivated.

The activated normal write pulse generator 100 may generate the normal write pulse N_wrp in response to a write command.

The selector 300 may provide the normal write pulse N_wrp to the memory cell 400 as the selection pulse S_wrp.

The memory cell 400 may store data corresponding to the selection pulse S_wrp. For example, the memory cell 400 may have a resistance value corresponding to a voltage level or a pulse width of the selection pulse S_wrp.

The sense amplifier controller 500 may receive the test activation signal T_act disabled in the normal operation and the sense amplifier enable signal SA_en. The sense amplifier controller 500 may enable the sense amplifier activation signal ACT_sa in response to the sense amplifier enable signal SA_en when the test activation signal T_act is disabled.

The sense amplifier 600 may sense and amplify the cell information C_imf provided from the memory cell 400 and output the amplified cell information C_imf as the data DATA in response to the sense amplifier activation signal ACT_sa generated according to the sense amplifier enable signal SA_en enabled in response to a read command.

As described above, in the normal operation, the semiconductor memory apparatus may store the data in the memory cell 400 by generating the normal write pulse N_wrp in response to the write command, and sense and amplify the cell information C_imf provided from the memory cell 400 to output the amplified cell information C_imf as the data DATA by driving the sense amplifier 600 in response to the read command.

In the test operation, the test write pulse generator 200 may be activated.

The test write pulse generator 200 may be activated by receiving the enabled test signal TM in the test operation.

The activated test write pulse generator 200 may enable the test activation enable signal T_act, and repeatedly generate the test write pulse T_wrp a preset number of times. The test write pulse generator 200 may disable the test activation signal T_act if the test write pulse T_wrp has generated the preset number of times.

The operation of the test write pulse generator 200 will be described in detail with reference to FIG. 2 below.

When the test signal TM is enabled, the latch unit 210 may enable the test activation signal T_act.

When the test activation signal T_act is enabled, the clock generator 220 may generate the clock CLK that periodically transitions between preset voltage levels.

When the test activation signal T_act is enabled, the output controller 230 may output the clock CLK as the test write pulse T_wrp.

When the test activation signal T_act is enabled, the counting unit 240 may disable the reset signal RST and count the number of pulses in the test write pulse T_wrp. The counting unit 240 may enable the reset signal RST if the test write pulses T_wrp have been generated the preset number of times.

When the reset signal RST is enabled, the latch unit 210 may disable the test activation signal T_act.

When the test activation signal T_act is disabled, the clock generator 220 is inactivated. The inactive clock generator 220 may maintain the clock CLK at a certain voltage.

When the test activation signal T_act is disabled, the output controller 230 may maintain the test write pulse T_wrp at a certain level (e.g., logic low level).

When the test activation signal T_act is disabled, the counting unit 240 may be inactivated, and stop the counting operation with respect to the test write pulse T_wrp. The counting unit 240 may enable the reset signal RST until the test activation signal T_act is enabled.

When the test signal TM is enabled, the test write pulse generator 200 may enable the test activation signal T_act, and repeatedly generate the test write pulse T_wrp the preset number of times. If the test write pulses T_wrp have been generated the preset number of times, the test write pulse generator 200 may disable the test activation signal T_act.

The sense amplifier controller 500 may disable the sense amplifier activation signal ACT_sa regardless of the sense amplifier enable signal SA_en in the period when the test activation signal T_act is enabled.

The sense amplifier 600 may be inactivated by receiving the disabled sense amplifier activation signal ACT_sa.

The sense amplifier 600 may be inactivated in the period when the test activation signal T_act is enabled (e.g., the period when the test write pulse T_wrp is repeatedly generated).

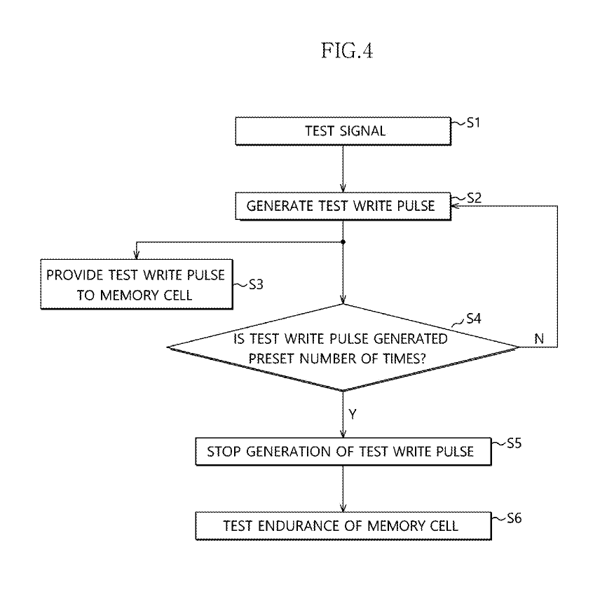

A test operation of the semiconductor memory apparatus according to an embodiment will be described with reference to FIG. 4. The test operation may be performed through a number of steps S1 to S6.

In the step S1, the test signal TM may be enabled.

In the step S2, after the test signal TM is enabled, the test write pulse T_wrp may be generated.

In the step S3, the test write pulse T_wrp may be provided to the memory cell 400.

In the step S4, whether or not the test write pulses T_wrp have been generated a preset number of times may be determined.

If the test write pulse T_wrp has not been generated the preset number of times, it may return to the step S2, and the test write pulse T_wrp may be generated again.

If the test write pulses T_wrp have been generated the preset number of times, the generation of the test write pulse T_wrp may be terminated (S5).

In the step S6, after the generation of the test write pulse T_wrp is terminated, an endurance test of the memory cell is performed. In the endurance test of the memory cell, data having a specific level may be written in the memory cell 400 using the normal write pulse generator 100, and then the data may be read out from the memory cell 400 as the cell information C_imf and it may be outputted as data DATA through the sense amplifier 600. Whether the memory cell 400 has passed or failed the test may be determined by checking whether or not original data, which has been written in the memory cell 400, is identical to the data read out from the memory cell 400.

The semiconductor memory apparatus according to an embodiment may continuously apply the test write pulses to the memory cell the preset number of times so as to perform the endurance test of the memory cell. The semiconductor memory apparatus according to an embodiment may determine an endurance cycle of the memory cell by storing data in the memory cell, reading out the stored data, and comparing the stored data with the read data after the test write pulses have been applied to the memory cell the preset number of times.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor memory apparatus comprising:
a normal write pulse generator configured to generate a normal write pulse in a normal operation;
a test write pulse generator configured to repeatedly generate a test write pulse a preset number of times in a test operation; and
a selector configured to provide the normal write pulse to a memory cell in the normal operation and provide the test write pulse to the memory cell in the test operation.

2. The semiconductor memory apparatus of claim 1, wherein the test write pulse generator repeatedly generates the test write pulse a preset number of times when a test signal is enabled and stops generating the test write pulse if the test write pulses have been generated the preset number of times.

3. The semiconductor memory apparatus of claim 2, wherein the test write pulse generator includes:
a latch unit configured to generate a test activation signal in response to the test signal and a reset signal;
a clock generator configured to generate a clock periodically transitioning between preset voltage levels in response to the test activation signal;
an output controller configured to output the test write pulse in response to the test activation signal and the clock; and
a counting unit configured to generate the reset signal in response to the test activation signal and the test write pulse.

4. The semiconductor memory apparatus of claim 3, wherein the latch unit enables the test activation signal when the test signal is enabled, and disables the test activation signal when the reset signal is enabled.

5. The semiconductor memory apparatus of claim 3, wherein the clock generator generates the clock periodically transitioning between the preset voltage levels during an enable period of the test activation signal.

6. The semiconductor memory apparatus of claim 3, wherein the output controller outputs the clock as the test write pulse during an enable period of the test activation signal, and maintains the test write pulse at a specific level when the test activation signal is disabled.

7. The semiconductor memory apparatus of claim 3, wherein the counting unit disables the reset signal and counts the number of pulses in the test write pulse when the test activation signal is enabled, and enables the reset signal when the number of pulses in the test write pulse reaches the preset number of times.

8. The semiconductor memory apparatus of claim 2, wherein the selector provides the test write pulse to the memory cell when the test signal is enabled, and provides the normal write pulse to the memory cell when the test signal is disabled.

9. The semiconductor memory apparatus of claim 2, further comprising a sense amplifier configured to read out data stored in the memory cell to which the test write pulses have been applied the preset number of times to check whether or not the read-out data is identical to original data.

10. A semiconductor memory apparatus comprising:
a normal write pulse generator configured to generate a normal write pulse;
a test write pulse generator configured to generate a test write pulse and a test activation signal in response to a test signal;
a selector configured to provide one of the normal write pulse and the test write pulse to a memory cell as a selection pulse in response to the test signal;
a sense amplifier controller configured to generate a sense amplifier activation signal in response to a sense amplifier enable signal and the test activation signal; and
a sense amplifier configured to sense and amplify cell information provided from the memory cell and output the amplified cell information as data in response to the sense amplifier activation signal.

11. The semiconductor memory apparatus of claim 10, wherein the test write pulse generator enables the test activation signal when the test signal is enabled, and maintains an enable state of the test activation signal until the test write pulses have been repeatedly generated a preset number of times.

12. The semiconductor memory apparatus of claim 11, wherein the test write pulse generator disables the test activation signal if the test write pulses have been generated the preset number of times.

13. The semiconductor memory apparatus of claim 12, wherein the test write pulse generator includes:
a latch unit configured to enable the test activation signal until a reset signal is enabled when the test signal is enabled;
a clock generator configured to generate a clock during an enable period of the test activation signal;
an output controller configured to output the clock as the test write pulse during the enable period of the test activation signal; and
the counting unit disables the reset signal when the test activation signal is enabled, and enables the reset signal when a number of times that the test write pulses are generated reaches the preset number of times.

14. The semiconductor memory apparatus of claim 10, wherein the selector outputs the normal write pulse as the selection pulse when the test signal is disabled, and outputs the test write pulse as the selection pulse when the test signal is enabled.

15. The semiconductor memory apparatus of claim 10, wherein the sense amplifier controller disables the sense amplifier activation signal regardless of the sense amplifier enable signal during the enable period of the test activation signal, and generates the sense amplifier activation signal in response to the sense amplifier enable signal when the test activation signal is disabled.

16. The semiconductor memory apparatus of claim 15, wherein the sense amplifier senses and amplifies cell information provided from the memory cell and outputs the amplified cell information as data when the sense amplifier activation signal is enabled.

17. A test method comprising:
enabling a test signal;
repeatedly generating a test write pulse when the test signal is enabled;
determining whether or not the test write pulses have been generated a preset number of times;
continuously generating the test write pulse until the test write pulses have been generated the preset number of times; and
testing endurance cycle of a memory cell when the generation of the test write pulse is stopped.

18. The test method of claim 17, further comprising providing the test write pulse to the memory cell.

19. The test method of claim 18, wherein testing the endurance of the memory cell when the generation of the test write pulse is stopped includes:
storing data having a specific level in the memory cell;
reading out data stored in the memory cell; and
determining whether or not the memory cell has passed or failed the test by comparing the data read out from the memory cell with original data.
